(19) United States
(12) Patent Application Publication
(10) Pub. No.: US 2025/0358973 A1
(43) Pub. Date: Nov. 20, 2025

(54) ELECTRONIC DEVICE WITH DEFORMABLE INTERNAL STRUCTURE

(71) Applicant: SK hynix Inc., Icheon-si (KR)

(72) Inventors: Ji Hoon KIM, Icheon-si (KR); Seung Yeob BAEK, Icheon-si (KR); Kyoung Soo CHO, Icheon-si (KR); Nam Hyeon CHOI, Icheon-si (KR)

(21) Appl. No.: 19/038,936

(22) Filed: Jan. 28, 2025

(30) Foreign Application Priority Data
May 20, 2024 (KR) 10-2024-0065249

(51) Int. Cl. H05K 7/20

(52) U.S. Cl. CPC H05K 7/20472; H05K 7/20518

(57) ABSTRACT

Provided herein may be an electronic device. The electronic device may include a housing providing an internal space and dissipating received heat, and a heat transfer structure transferring heat generated from a heater to a portion of the housing in response to gravity. The heat transfer structure may transfer the heat to a first surface of the housing corresponding to a forward direction of the gravity, and may form an air gap between a second surface of the housing corresponding to a reverse direction of the gravity and the heat transfer structure.

### CROSS-REFERENCE TO RELATED APPLICATION

The present application claims priority under 35 U.S.C. § 119(a) to Korean patent application number 10-2024-0065249 filed on May 20, 2024, in the Korean Intellectual Property Office, the entire disclosure of which is incorporated by reference herein.

### BACKGROUND

### 1. Technical Field

Various embodiments of the present disclosure generally relate to an electronic device, and more particularly to an electronic device having a deformable internal structure.

### 2. Related Art

Heat may be generated from a memory device included in an electronic device. When the temperature of the electronic device increases, the performance of the electronic device may deteriorate. A case including the electronic device may dissipate heat generated in the electronic device to maintain the temperature of the electronic device within a certain range.

The operating electronic device may be dissipating heat to manage its temperature. There is a risk of injury if a user touches the electronic device while it is dissipating heat. Particularly, in the case of a portable electronic device, the user may contact a specific surface of the operating electronic device. For the safety of the user, it is preferable to dissipate heat through a safe surface of the electronic device.

### SUMMARY

Various embodiments of the present disclosure are directed to an electronic device that determines usage environment based on the direction of gravity, and dissipating internally generated heat to a bottom surface in contact with an object.

An embodiment of the present disclosure may provide for an electronic device. The electronic device may include a housing with an internal space that dissipates received heat, and a heat transfer structure transferring generated heat from a heater to the housing, and the heat transfer structure may transfer the generated heat to a first surface of the housing and is disposed with an air gap between a second surface of the housing and the heat transfer structure. The first surface of the housing is disposed in a direction toward gravity relative to the heat transfer structure and the second surface of the housing is disposed in a direction reversed from the direction toward gravity relative to the heat transfer structure.

An embodiment of the present disclosure may provide for an electronic device. The electronic device may include a first housing corresponding to a forward direction of gravity and dissipating received heat, a second housing corresponding to a reverse direction of the gravity and coupled to the first housing to provide an internal space, a heat transfer structure moving in response to gravity in the internal space, and a heater including memory elements that generate heat and contacting a portion of an inner surface of the heat transfer structure, and the heat transfer structure may transfer the heat to the first housing and the second housing and the heat transfer structure are disposed with an air gap therebetween.

### BRIEF DESCRIPTION OF THE DRAWINGS

FIG. 1 is a view illustrating an electronic device according to an embodiment of the present disclosure.

FIG. 2 is a view illustrating a heat transfer structure relative to a forward and reverse direction of gravity according to an embodiment of the present disclosure.

FIG. 3 is a view illustrating a heat transfer structure of FIG. 2 and heat transfer material.

FIG. 4 is a view illustrating the movement of a heat transfer structure when an electronic device of FIG. 2 is turned over.

FIG. 5 is a view illustrating a heat transfer structure of FIG. 4 and heat transfer material.

FIG. 6 is a view illustrating a heat conduction sheet on an inside of a heat transfer structure according to an embodiment of the present disclosure.

### DETAILED DESCRIPTION

Specific structural or functional descriptions in embodiments of the present disclosure introduced in this specification or application are only for description of these embodiments of the present disclosure. The descriptions should not be construed as being limited to only the embodiments described in the specification or application.

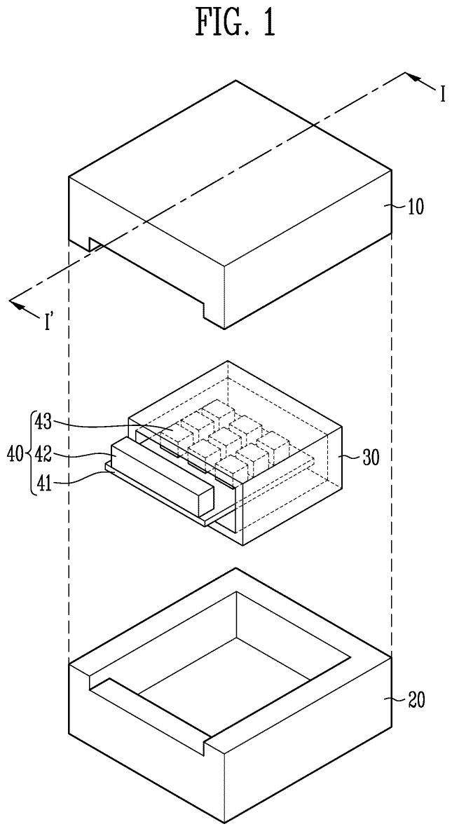

FIG. 1 is a view illustrating an electronic device according to an embodiment of the present disclosure.

FIG. 1 illustrates an electronic device where dotted lines indicate components may be moved to couple to each other. The electronic device may include an upper housing 10, a lower housing 20, a heat transfer structure 30, and a heater (or a heating element) 40. A case of the electronic device may be composed of the upper housing 10 and the lower housing 20. The upper housing 10 and the lower housing 20 may be coupled to define the internal space of the case. The heat transfer structure 30 and the heater 40 may be arranged in the internal space of the case. The components illustrated in FIG. 1 are briefly illustrated for convenience of explanation, and actual sizes and proportions of the components may vary.

The upper housing 10 and the lower housing 20 may be recessed inward to provide the internal space. The upper housing 10 and the lower housing 20 may be coupled to each other. The upper housing 10 and the lower housing 20 may dissipate heat received from or generated in the internal space.

The upper housing 10 and the lower housing 20 may include a heat dissipation material. For example, the upper housing 10 and the lower housing 20 may each include aluminum or aluminum alloy, and more specifically, may include die-cast aluminum or aluminum alloy. The upper housing 10 and the lower housing 20 usually include the same material, but in other embodiments may include different materials.

The heat transfer structure 30 may move within the internal space, especially in the direction of gravitational force. The heat transfer structure 30 may be formed of a metal material. The heat transfer structure 30 may have the shape of a cover or a cover-like or case-like structure enclosing the heater 40. As the heat transfer structure 30 moves within the internal space, the heat transfer structure 30 may contact a surface of the heater 40 and receive heat from the heater 40 through conduction or convection. The heat transfer structure 30 may transfer the received heat to the upper housing 10 or the lower housing 20 depending on the direction of the gravitational forces relative to the electronic device.

The heater 40 may include a circuit board 41, a connector 42, and memory elements 43. The connector 42 and the memory elements 43 may be electrically connected to the circuit board 41. The connector 42 may connect an external device to the electronic device through an opening in the case of the electronic device as illustrated in FIG. 1. Data and signals may be transmitted and received through the connector 42.

The memory elements 43 may be non-volatile memory chips or volatile memory chips. A non-volatile memory chip may be a NAND or flash memory chip. A volatile memory chip may operate as a buffer memory. Although simply and identically illustrated in FIG. 1, the number, size, height, and location of the memory elements 43 may vary. Further, the memory elements 43 may be of different memory types. The height of the memory elements mounted on the circuit board 41 may also vary depending on the types of the memory elements.

Although not illustrated in FIG. 1, the circuit board 41 may further include passive elements and a controller. The passive elements may be resistors, capacitors, inductors, thermistors, oscillators, ferrite beads, etc. The elements mounted on the circuit board 41 may be electrically connected. The controller may control the operations of the memory elements 43 and passive elements mounted on the circuit board 41. The controller may transmit and receive data and signals to and from a host device.

In an embodiment of the present disclosure, the circuit board 41 and elements mounted on the circuit board 41 may be collectively referred to as the heater 40. The heater 40 may generate heat when the memory elements 43 or the controller operates. Heat generated by the heater 40 may increase the temperature of the electronic device. When the temperature of the electronic device increases due to the heat generated by the heater 40, the performance of the electronic device may deteriorate. In order to maintain the performance of the electronic device, a heat management operation for dissipating the generated heat is required.

The heat transfer structure 30 may transfer heat generated by the heater 40 to the upper housing 10 or the lower housing 20. The heat transfer structure 30 may receive heat, which is to be dissipated, through contact with the heater 40. The heat transfer structure 30 may transfer the received heat through the contact with the upper housing 10 or the lower housing 20. When the heat transfer structure 30 is in contact with the upper housing 10, an air gap may form between the heat transfer structure 30 and the lower housing 20, which is not in contact with the heat transfer structure 30. Similarly, when the heat transfer structure 30 is in contact with the lower housing 20, an air gap may form between the heat transfer structure 30 and the upper housing 10, which is not in contact with the heat transfer structure 30. Air gaps tend to block the transfer of heat, thereby preventing some of the heat generated by the heater 40 from being transferred through the electronic device to the user.

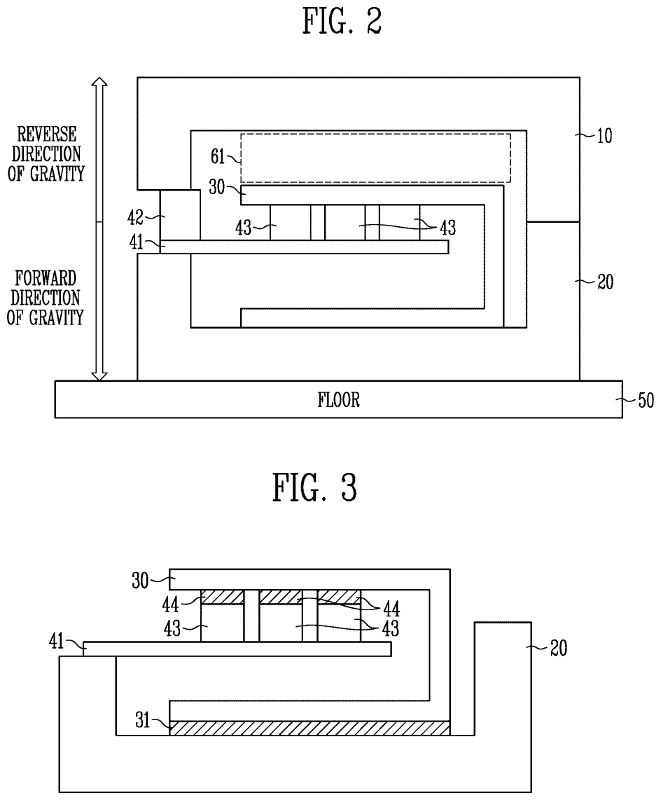

FIG. 2 is a view illustrating a heat transfer structure that relative to a forward and reverse direction of gravity according to an embodiment of the present disclosure.

FIG. 2 illustrates a cross-sectional view of an electronic device taken along line I-I′ of FIG. 1. Hereinafter, the electronic device of the present disclosure may be assumed to be a movable or portable storage device. The electronic device may be connected to another electronic device via a connector 42, and a case of the electronic device may be in a form in which an upper housing 10 and a lower housing 20 are coupled. Descriptions of components of FIG. 2 that are the same as components described above with reference to FIG. 1 may be omitted below.

In FIG. 2, the lower housing 20 is placed on a floor 50 while in use. The floor 50 may spread the heat emitted by the lower housing 20 to areas surrounding the floor. Since a forward direction of gravity is toward the floor 50, the lower housing 20 is a first housing corresponding to the forward direction of gravity. Likewise, the upper housing 10 is a second housing corresponding to a reverse direction of gravity. In FIG. 2, among surfaces of the lower housing 20, a surface of the lower housing common to the internal space and perpendicular to the direction of gravity may be a first surface of the housing corresponding to the forward direction of gravity. Similarly, among surfaces of the upper housing 10, a surface of the upper housing 10 common to the internal space and perpendicular to the direction of gravity may be a second surface corresponding to the reverse direction of gravity.

In an embodiment of the present disclosure, the heat transfer structure 30 may be move along the forward direction of gravity. The heat transfer structure 30 may move in the forward direction of gravity within the internal space, which is defined by coupling the upper housing 10 and lower housing 20 to each other, until the heat transfer structure 30 contacts the lower housing 20.

The heat transfer structure 30 may receive heat generated when it contacts a surface of the heater. In FIG. 2, an inner surface of the heat transfer structure 30 is in contact with memory elements 43. The heat transfer structure 30 may transfer heat, received from the memory elements 43 primarily through conduction, to the lower housing 20. The heat transfer structure may include metal materials.

The heater 40 may generate heat when the storage device operates. Heat may be generated not only in the memory elements 43 but also in the circuit board 41 and the connector 42. In FIG. 2, the memory elements 43 contact the heat transfer structure 30, but heat generated by other components in the heater 40 may also be transferred through the memory elements 43 to the heat transfer structure 30.

When the heat transfer structure 30 moves along the forward direction of gravity, an air gap may be formed in the internal space. For example, an air gap 61 may be formed between the heat transfer structure 30 and the upper housing 10 to limit the transfer of heat generated by the heater 40 to the upper housing 10. The air gap 61 is a fixed air layer that does not move and has very low heat conductivity. In an embodiment of the present disclosure, the fixed air layer may be referred to as solid air.

The air gap 61 may block heat generated by the heater 40 from being transferred to the upper housing 10. A user of the electronic device is unlikely to contact the bottom surface of the electronic device, which contacts the floor 50, and instead the user directly touches an upper surface of the electronic device that does not contact the floor. Since the air gap 61 limits or prevents the transfer of heat generated by the heater 40 to an upper surface of the electronic device, the user may safely use a movable storage device. In addition, since the heat generated by the heater 40 is dissipated through the lower housing 20, the temperature of the storage device can be managed.

FIG. 3 is a view illustrating a heat transfer structure of FIG. 2 and heat transfer material.

Referring to FIG. 3, heat transfer materials 31 and 44 may be located between a heat transfer structure 30 and the lower housing 20 or the heater 40, respectively. For convenience of explanation, components of the electronic device other than those in contact with the heat transfer structure 30 may be omitted in FIG. 3.

In FIG. 3, when the heat transfer structure 30 receives heat by contacting memory elements 43, the heat transfer material 44 may be added between the inner surface of the heat transfer structure 30 and the upper surface of each memory elements 43. When the heat transfer structure 30 contacts the lower housing 20 to transfer heat that is to be dissipated, the heat transfer material 31 may be added between the heat transfer structure 30 and the lower housing 20.

The efficiency of heat transfer may be reduced by any small gaps between objects exchanging heat. The small gap between the objects that exchange heat may be filled with air. Since air is a material with low heat conductivity, an actual contact area through which heat is transferred is reduced by the small gaps. Heat transfer efficiency decreases when the actual contact area is reduced.

The heat transfer material may fill small gaps between objects exchanging heat. The heat transfer may be efficiently performed using the heat transfer material. For example, the heat transfer material may include a polymer material for interfacial adhesion and ceramic or carbon fiber for heat conductivity. The heat transfer material may be in the form of a solid (gap pad), a liquid (gap filler), an adhesive, or a putty.

In an embodiment of the present disclosure, the heat transfer materials 31 and 44 may not only increase the heat transfer efficiency, but also prevent or reduce damage to the electronic device due to the movement of the heat transfer structure 30. Contact impact or stress may occur at a contact surface due to contact with the heat transfer structure 30. This may cause physical damage to the electronic device. The heat transfer materials 31 and 44 may be located between the objects that exchange heat, thereby minimizing damage caused by direct contact. The heat transfer materials 31 and 44 may include elastic materials.

In an embodiment of the present disclosure, the heat transfer material 31 and the heat transfer material 44 may be the same material or may be different materials depending on the properties of the objects that contact each other. The heat transfer materials 31 and 44 illustrated in FIG. 3 are examples, and the size and thickness of the heat transfer materials 31 and 44 may vary.

In FIG. 3, the heat transfer structure 30 is illustrated without one side of the structure facing a rectangular parallelepiped connector 42, but this is only an example. The heat transfer structure 30 may have various shapes, such as a shape that substantially covers or envelops the heater 40. That is, the shape of the heat transfer structure 30 may be a rectangular parallelepiped without one side missing, or various shapes that match the arrangement of semiconductor elements mounted on the circuit board 41 or the internal space of the electronic device. Although not illustrated in FIG. 3, in some embodiments a moving line may protrude into the internal space of the electronic device (formed for example by protrusions from internal surfaces of the upper housing 10 and the lower housing 20), and the heat transfer structure 30 may have a groove corresponding to the protruding moving line, which guides the movement of the heat transfer structure within the internal space.

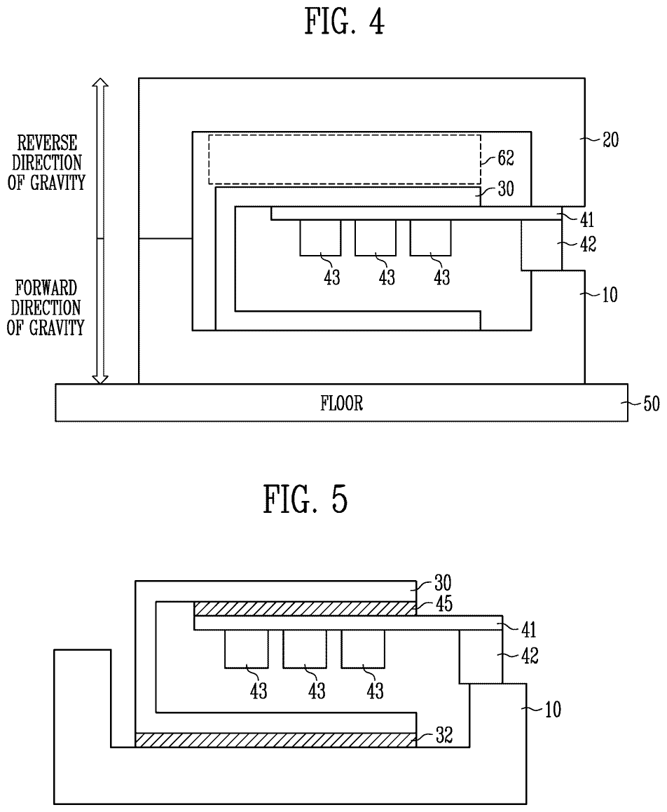

FIG. 4 is a view illustrating the movement of a heat transfer structure when an electronic device of FIG. 2 is turned over.

In FIG. 4, a cross-sectional view taken along line I-I′ of FIG. 1 is illustrated when an electronic device of FIG. 2 is flipped or turned over. In FIG. 4, an upper housing 10 of the electronic device is placed onto a floor 50. In FIG. 4, the upper housing 10 may dissipate heat through the floor 50, and a lower housing 20, which may come into contact with a user, may block or reduce the transfer of heat, generated by the heater 40, to the user during contact. Descriptions of components of FIG. 4 that are the same as components described above with reference to FIG. 2 may be omitted below.

In FIG. 4, the upper housing 10 is a first housing corresponding to the forward direction of gravity, while the lower housing 20 is a second housing corresponding to the reverse direction of gravity. The heat transfer structure 30 may move along the forward direction of gravity in the internal space until it comes into contact with the upper housing 10. Likewise, a surface of the upper housing common to the internal space and perpendicular to the direction of gravity, from among the surfaces of the upper housing 10, may be a first surface of the housing corresponding to the forward direction of gravity. Similarly, among surfaces of the lower housing 20, a surface of the lower housing common to the internal space and perpendicular to the direction of gravity may be a second surface of the housing corresponding to the reverse direction of gravity. In an embodiment of the present disclosure, depending on the direction in which gravitational forces act, the first housing and the second housing or the first surface of the housing and the second surface of the housing may be determined.

As the heat transfer structure 30 moves within the internal space, an air gap 62 may be formed between the lower housing 20 and the heat transfer structure 30. The air gap may block or restrict heat transfer from a circuit board 41 through the heat transfer structure 30 to the lower housing 20. The heat transfer structure 30 may receive heat generated by the heater 40 through contact with a surface of the heater 40. In FIG. 4, an inner surface of the heat transfer structure 30 contacts the circuit board 41. The heat transfer structure 30 may transfer heat received from the circuit board 41 to the upper housing 10. Heat may be generated from the heater 40 as the storage device operates. The heat generated by the heater 40 may be transferred through the circuit board 41 to the heat transfer structure 30.

FIG. 5 is a view illustrating a heat transfer structure of FIG. 4 and heat transfer material.

Referring to FIG. 5, heat transfer materials 32 and 45 may be located between the heat transfer structure and the upper housing 10 or the heater 40, respectively. For convenience of explanation, components of the electronic device other than those in contact with the heat transfer structure 30 may be omitted in FIG. 5. Descriptions of components of FIG. 5 that are the same as components described above with reference to FIGS. 3 and 4 may be omitted below.

In FIG. 5, when the heat transfer structure 30 receives heat through contact with the circuit board 41, the heat transfer material 45 may be added between the inner surface of the heat transfer structure 30 and a lower surface of the circuit board 41. When the heat transfer structure 30 contacts the upper housing 10 to transfer heat to be dissipated, the heat transfer material 32 may be added between the heat transfer structure 30 and the upper housing 10.

Similar to FIG. 3, the heat transfer materials 32 and 45 may increase heat transfer efficiency by filling any gaps between objects in contact to exchange heat, and may prevent physical damage that may occur due to the movement of the heat transfer structure 30 against other components. In an embodiment of the present disclosure, the heat transfer material 32 and the heat transfer material 45 may be the same material or be different materials depending on the physical properties of the circuit board 41 and the upper housing 10 that are in contact with the heat transfer structure 30.

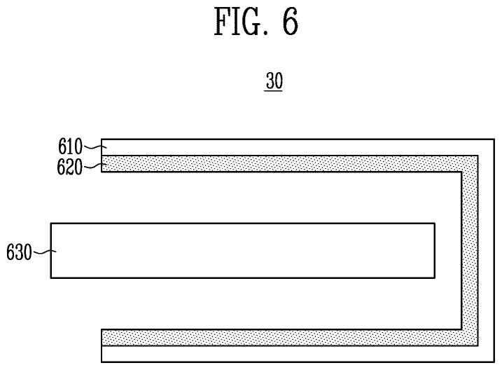

FIG. 6 is a view illustrating a heat conduction sheet on an inside of a heat transfer structure according to an embodiment of the present disclosure.

Referring to FIG. 6, a heat transfer structure 30 in a shape covering part of a heater 630 may be illustrated in a cross-sectional view. For convenience of explanation, the shape of the heater 630 is simply illustrated. As illustrated in FIG. 3, the shape of the heat transfer structure 30 may vary. For convenience of explanation, in FIG. 6, the heat transfer structure 30 may be illustrated as a rectangular parallelepiped with one side omitted. An interior of the heat transfer structure 30 may be open or empty.

The heat transfer structure 30 inside of an electronic device may move in response to the rotation or inversion of the electronic device. The heat transfer structure 30 may continue to move until a surface of the heat transfer structure 30 comes into contact with a surface of a heater 630 inside the electronic device or the housing of the electronic device.

The heat transfer structure 30 may be made of a metal material. Since a metal material has high heat conductivity, the heat transfer structure 30 may transfer heat received from the heater 630 to the housing, which dissipates the heat. In an embodiment of the present disclosure, the heat transfer structure 30 may include a heat conduction sheet 620 attached to an inside surface of a heat transfer structure 610 made of a metal material.

The heat conduction sheet 620 may spread the received heat in a planar direction. The heat conduction sheet 620 may be attached to the heat transfer structure 610 made of a metal material, thereby allowing the heat transferred from the heater 630 to be more quickly spread in a planar direction. Since an area through which heat is transferred may be increased using the heat conduction sheet 620, heat transfer efficiency can be increased. In an embodiment of the present disclosure, the heat conduction sheet 620 may be a graphite sheet.

Although not illustrated in FIG. 6, a heat transfer material may be included between the heat transfer structure 30 and the heater 630. In an embodiment of the present disclosure, a heat transfer material may be included between the heat conduction sheet 620 attached to the heat transfer structure 610 and the heater 630. The heat transfer material fills physical gaps between the heater 630 and the heat transfer structure 30, thereby increasing heat transfer efficiency between objects that are exchanging heat, and the heat conduction sheet 620 may increase the speed at which heat spreads through the heat transfer structure 610 made of a metal material. Heat transfer efficiency can be improved using the heat transfer material and the heat conduction sheet 620.

The present disclosure provides an electronic device that dissipates heat generated in the electronic device through a surface of the electronic device in the direction of a gravitational force by moving a heat transfer structure along the direction of the gravitational force in an internal space of the electronic device.

What is claimed is:

1. An electronic device, comprising:
a housing with an internal space that dissipates received heat; and
a heat transfer structure transferring generated heat from a heater to the housing,
wherein the heat transfer structure transfers the generated heat to a first surface of the housing and is disposed with an air gap between a second surface of the housing and the heat transfer structure, and
wherein the first surface of the housing is disposed in a direction toward gravity relative to the heat transfer structure and the second surface of the housing is disposed in a direction reversed from the direction toward gravity relative to the heat transfer structure.

2. The electronic device according to claim 1, wherein the heat transfer structure moves in the direction toward gravity within the internal space.

3. The electronic device according to claim 2, wherein:
the air gap blocks transfer of the generated heat to the second surface, and
the heat transfer structure contacts the first surface of the housing.

4. The electronic device according to claim 3, further comprising:
a heat transfer material disposed between the first surface of the housing and the heat transfer structure.

5. The electronic device according to claim 2, wherein the heater is disposed inside of the heat transfer structure and transfers the generated heat to the heat transfer structure through contact with an inner surface of the heat transfer structure.

6. The electronic device according to claim 5, wherein, in response to movement of the heat transfer structure in the direction reversed from the direction toward gravity, a surface of the heater contacts a portion of the inner surface of the heat transfer structure.

7. The electronic device according to claim 6, further comprising:
a heat conduction sheet disposed on the inner surface of the heat transfer structure.

8. The electronic device according to claim 6, wherein the heater comprises memory elements, a controller configured to control the memory elements, and a circuit board electrically connecting the memory elements to the controller.

9. The electronic device according to claim 6, further comprising:
a heat transfer material disposed between the surface of the heater and the inner surface of the heat transfer structure.

10. An electronic device, comprising:
a first housing corresponding to a forward direction of gravity, and dissipating received heat;
a second housing corresponding to a reverse direction of gravity, and coupled to the first housing to provide an internal space;
a heat transfer structure moving in response to gravity in the internal space; and
a heater including memory elements that generate heat, and contacting a portion of an inner surface of the heat transfer structure,
wherein the heat transfer structure transfers heat to the first housing, and the second housing and the heat transfer structure are disposed with an air gap therebetween.

11. The electronic device according to claim 10, wherein the heat transfer structure moves to contact the first housing in the forward direction of gravity in the internal space.

12. The electronic device according to claim 11, further comprising:
a heat transfer material between the heat transfer structure and the first housing.

13. The electronic device according to claim 12, wherein the heat transfer structure is a cover-like metal structure covering the heater.

14. The electronic device according to claim 13, wherein the heater transfers heat through contact with a portion of the inner surface of the heat transfer structure.

15. The electronic device according to claim 14, further comprising:
a heat transfer material between a surface of the heater and the inner surface of the heat transfer structure.

16. The electronic device according to claim 13, further comprising:
a heat conduction sheet disposed on the inner surface of the heat transfer structure.
